(19) United States
(12) Patent Application Publication
(10) Pub. No.: US 2010/0214277 A1
(43) Pub. Date: Aug. 26, 2010

(54) OUTPUT CIRCUIT AND DRIVING CIRCUIT FOR DISPLAY DEVICE

(75) Inventors: Koji Yamazaki, Ibaraki (JP); Kenichi Shiibayashi, Chiba (JP); Atsushi Hirama, Tokyo (JP)

Correspondence Address: VOLENTINE & WHITT PLLC, ONE FREEDOM SQUARE, 11951 FREEDOM DRIVE SUITE 1260, RESTON, VA, 20190, US

(73) Assignee: OKI SEMICONDUCTOR CO., LTD., Tokyo (JP)

(21) Appl. No.: 12/709,535

(22) Filed: Feb. 22, 2010

(30) Foreign Application Priority Data
Feb. 26, 2009 (JP) 2009-044362
Jul. 16, 2009 (JP) 2009-168212

(51) Int. Cl. G09G 3/36; H03F 1/34; G09G 5/00

(52) U.S. Cl. 345/211; 330/110; 345/87

(57) ABSTRACT

The present invention provides an output circuit that can suppress a voltage drop in an output section of the output circuit and that can suppress a phase delay of an output signal which is feedbacked to an input section of the output circuit. An AC component of a data signal output from an output terminal of an operational amplifier to which an input signal is input, is negatively feedbacked via a capacitor, and is input to an inverting input terminal of the operational amplifier. A DC component of the data signal output from the output terminal, is lowered its potential by a second protective resistor to the same potential as the input signal and is output as an output signal to data lines via respective output pads, and is output to an inverting input terminal of the operational amplifier via a first protective resistor.

### CROSS-REFERENCE TO RELATED APPLICATION

This application claims priority under 35 U.S.C. 119 from Japanese Patent Application No. 2009-044362 filed on Feb. 26, 2009, and Japanese Patent Application No. 2009-168212 filed on Jul. 16, 2009, the disclosures of which are incorporated by reference herein.

### BACKGROUND OF THE INVENTION

1. Field of the Invention

The present invention relates to an output circuit and a driving circuit for a display device. Specifically, the present invention relates to an output circuit provided in a driving circuit for display device such as the FED (Field Emission Display) or the like, and also relates to a driving circuit of the display device.

2. Description of the Related Art

In the output circuit provided in the conventional driving circuit of the display device, an ESD (Electro Static Discharge) protection resistor is provided between an output section and a feedback section of the operational amplifier. By this protection resistor, damage to the operational amplifier caused by ESD is protected, and a potential drop in the output section by the ESD protection resistor is suppressed. (See Japanese Patent Application Publication No. 2005-201974)

However, in a output circuit provided in the driving circuit disclosed in Japanese Patent Application Publication No. 2005-201974, a phase of the output signal, which is feedbacked to an input section of the operational amplifier, delays by a parasitic capacitance of the operational amplifier and the ESD protection resistance. As a result, in the above driving circuit, the output signal may oscillate easily.

### SUMMARY OF THE INVENTION

The present invention is to provide an output circuit and a driving circuit for a display device that can suppress a voltage drop by the ESD protection resistance in the output section, that can suppress a phase delay in an output signal which is feedbacked to the input section of the output circuit, and that can maintain a stable oscillation of the output circuit.

A first aspect of the present invention is an output circuit including: an impedance conversion section, that includes an output terminal and a feedback input terminal, and that converts impedance; a first resistor that includes a first end connected to the output terminal of the impedance conversion section, and a second end connected to a load; a second resistor that includes a first end connected to the second end of the first resistor, and a second end connected to the feedback input terminal of the impedance conversion section; and a capacitor that includes a first end connected to the output terminal of the impedance conversion section, and a second end connected to the feedback input terminal of the impedance conversion section.

According to the first aspect of the present invention, the output terminal of the impedance conversion section is connected to one end of the first resistor and one end of the capacitor. Further, opposite end of the first resistor is connected to one end of the second resistor and a liquid crystal panel. Furthermore, opposite end of the second resistor and opposite end of the capacitor is connected to the feedback input of the impedance conversion section. Due thereto, the first aspect of the present invention can suppress the delay of the phase in the signal that are inputted to the feedback input of the impedance conversion section.

In a second aspect of the present invention, in the first aspect, the first resistor and the second resistor may be protective resistors for an accumulated static charge.

According to the second aspect of the present invention, the first resistor and the second resistor are configured as protective resistors. Accordingly, the second aspect of the present invention can prevent the impedance conversion section to be damaged by the ESD.

In a third aspect of the present invention, in the first aspect, the impedance conversion section may be an operational amplifier, and wherein the feedback input terminal may be an inverting input terminal of the operational amplifier.

According to the third aspect of the present invention, the potential of the signal output to the load can be made the same potential as the input signal which is input to the operational amplifier.

A fourth aspect of the present invention is a display device driving circuit for driving a display device including: a plurality of output circuits according to the first aspect, wherein the impedance conversion section is a driver that drives the display device as the load, based on an output signal outputted from the output terminal.

According to the fourth aspect of the present invention, plural output circuits can be used to drive the display device that operates as the load, based on the signals output from the output terminal of the impedance conversion sections.

In a fifth aspect of the present invention, the in the fourth aspect, the display device may be driven by electric current that flows corresponding to the output signal output from the output terminal of the impedance conversion section.

According to the fifth aspect of the present invention, the display device can be driven by the current that flows corresponding to the signal the output from the output terminal of the impedance conversion section.

In a sixth aspect of the present invention, in the fifth aspect, the display device may be a liquid crystal display device.

According to the sixth aspect of the invention, a light transmittance rate of liquid crystal element of the liquid crystal display device can be changed to transmit light or to block light.

### BRIEF DESCRIPTION OF THE DRAWINGS

Exemplary embodiments of the present invention will be described in detail based on the following figures, wherein:

FIG. 1 is diagram showing a schematic configuration of a liquid crystal display device according to an exemplary embodiment of the present invention; and

FIG. 2 is a configuration diagram showing a driving circuit of the liquid crystal display device according to the exemplary embodiment of the present invention.

### DETAILED DESCRIPTION OF THE INVENTION

An exemplary embodiment of the present invention will be described in detail with reference to the drawings.

Hereinafter, an exemplary embodiment where the present invention is applied to a voltage follower circuit of the driving circuit of the liquid crystal display, and where an operational amplifier is used as an impedance conversion section, will be described.

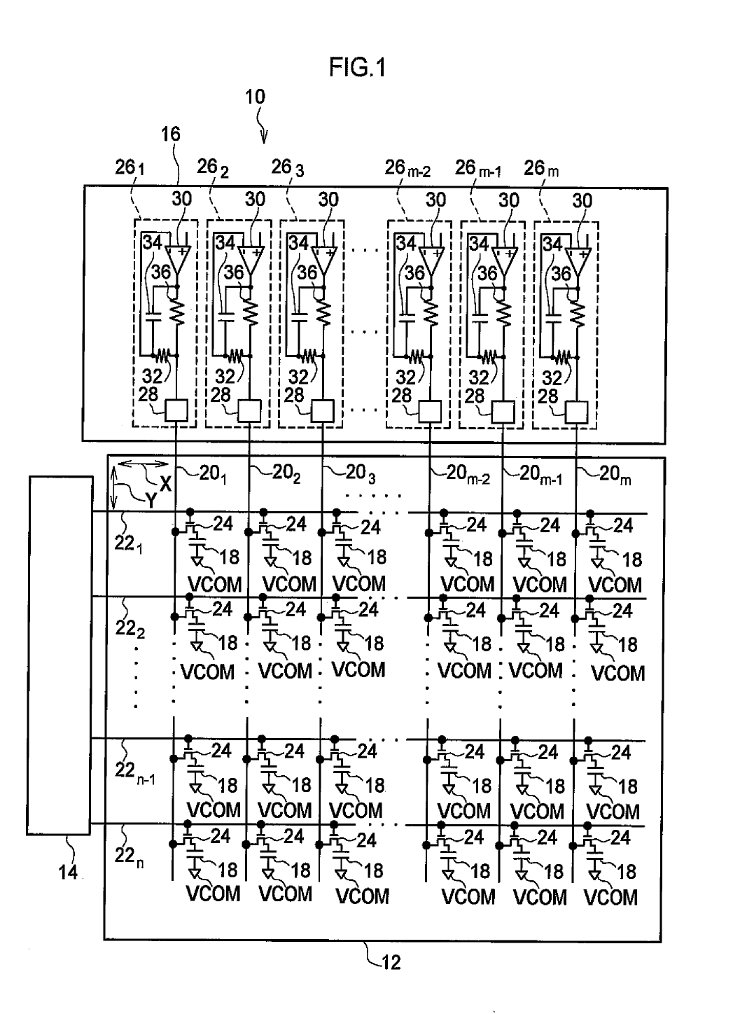

As shown in FIG. 1, the liquid crystal display device 10 according to the present exemplary embodiment includes a liquid crystal panel 12 that functions as a display device, a gate driving circuit 14, and a source driving circuit 16.

As shown in FIG. 1, the liquid crystal panel 12 includes plural pixel capacitance 18 of liquid crystal cells, m data lines 20₁ to 20ₘ, n gate lines 22ᵢ to 22ₖ, and TFTs 24 (Thin Film Transistor). In each pixel capacitance 18 of the liquid crystal cell, liquid crystal is sealed between a pair of transparent electrodes (not shown) that are separated by a fixed interval and are opposing to each other. Further, m data lines 20₁ to 20ₘ are provided with a constant interval therebetween in the X-direction, and extends toward the Y-direction. Similarly, n gate lines 22₁ to 22ₙ are provided with a constant interval therebetween in the Y-direction, and extends toward the X-direction. The TFTs 24 are each provided adjacent to the respective intersections (e.g., pixel locations) of the m data lines 20₁ to 20ₘ and the n gate lines 22₁ to 22ₙ.

One out of the transparent electrodes of each pixel capacitance 18 of the liquid crystal cell is connected to a drain terminal of the TFT 24. Further, the other transparent electrode of each pixel capacitance 18 of the liquid crystal cell is connected to portion that has a predetermined reference potential VCOM.

A source terminal of each TFT 24 is connected to a respective data line 20 and a gate terminal of each TFT 24 is connected to a respective gate line 22.

The gate driving circuit 14 includes n driving circuits, where each driving circuit is connected to respective gate lines 22₁ to 22ₙ.

Further, the source driving circuit 16 is configured by m driving circuits 26₁ to 26ₘ. The m driving circuits 26₁ to 26ₘ has the same configuration, and are connected to respective data lines 20₁ to 20ₘ.

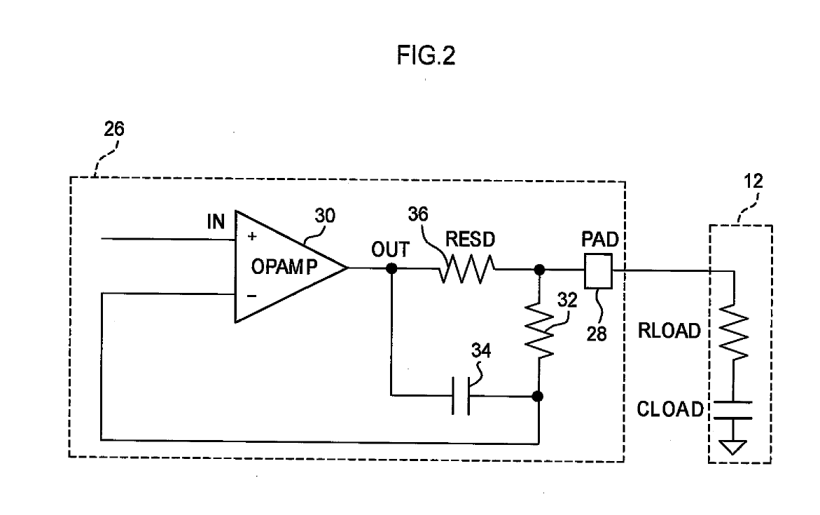

Hereinafter, explanation will be given to one of the driving circuits 26₁ to 26ₘ, by referring to FIG. 2.

As shown in FIG. 2, an operational amplifier executes a rail-to-rail operation, and includes a non-inverting input terminal connected to an input signal generating section (not shown). Further, an inverting input terminal of the operational amplifier 30 is connected to one end of a first protective resistor 32. Together therewith, the inverting input terminal of the operational amplifier 30 is connected to one end of a capacitor 34. The first protective resistor 32 protects damages from the discharge of static charges, charged in the output pad 28 or the like. The capacitor 34 negative feedbacks the data signal output from the output terminal of the operational amplifier 30 without a phase delay, to the inverting input terminal. Further, the output terminal (OUT) is connected to the other end of the first protective resistor 32 and the output pad 28, via a second protective resistor 36. The second protective resistor 36 protects the output terminal (OUT) of the operational amplifier from the damages caused by the discharge of static charges, charged in the output pad 28 or the like. Note that, the first protective resistor 32 corresponds to a second resistor of the present invention. Further, the second protective resistor 36 corresponds to a first resistor of the present invention.

Further, the output pads 28 are connected to the liquid crystal panel 12 via respective data lines 20.

Next, operation of the liquid crystal display device 10, is described. When the gate signal is input from the gate driving circuit 14 to a single gate line 22 for a predetermined duration, the TFTs 24 connected to this single gate line 22 is set into an ON state.

Thereafter, when an input signal that has a higher potential than the reference potential VCOM is inputted from the input signal generating section (not shown) to the non-inverting terminal of one or more operational amplifiers 30 for a predetermined duration, data signal is output from the output terminal (OUT) of the operational amplifiers 30.

An AC (alternating current) component of the data signal, output from the output terminal of the operational amplifiers 30 of which the input signal is inputted, is negatively feedbacked via the capacitor 34. Then, the AC component of the data signal is inputted to the inverting input terminal of the operational amplifiers 30. Further, DC component of data signal output from the output terminal (OUT) of an operational amplifier 30, is lowered its potential by the second protective resistor 36 to the same potential as the input signal, and is output as an output signal to data lines 20 via respective output pads 28. Together therewith, the DC component of data signal which is the lowered its potential, is input to the inverting input terminal of the operational amplifier 30 via the first protective resistor 32.

Next, when the data signal is inputted by the data line 20, that data signal is inputted to the source terminal of TFT 24 connected to the data line 20.

When the data signal is inputted to the source terminal of the TFT 24 which is in an ON state by the input of the gate signal, a drain current flows into the pixel capacitance 18 of the liquid crystal cell from the drain terminal of TFT 24 via source terminal of TFT 24. Due thereto, the pixel capacitance 18 of the liquid crystal cell starts charging and a light transmittance rate of the liquid crystals changes. Accordingly, a portion of an image equivalent to one line of the liquid crystal panel 12 becomes displayed.

Then, the gate driving circuit 14 switches from the current gate line to a next gate line, and the above-described processes are repeated. Accordingly, the entire image is displayed on the liquid crystal panel 12.

When an input signal that has a lower potential than the reference potential VCOM is inputted from the input signal generating section (not shown) to the non-inverting terminal of one or more operational amplifiers 30 for a predetermined duration, data signal is output from the output terminal (OUT) of the operational amplifiers 30.

Note that, the output terminal (OUT) is connected to the pixel capacitance 18 of the liquid crystal cells through the second protective resistors 36, the output pads 28, the data lines 20 and the TFTs 24. Out of the pixel capacitance 18 of the liquid crystal cells that are connected to the output terminal (OUT) that has outputted the data signal, the pixel capacitance 18 of the liquid crystal cells connected to the drain terminal of the TFTs 24 that are in the ON state, start discharging the electric charge stored therein. Accordingly, the light transmittance rate of the liquid crystal cells changes.

Further, the discharge current discharged from the pixel capacitance 18 of the liquid crystal cells, flows through the data lines 20, the output pads 28, the second protective resistors 36, and the output terminal (OUT) of the operational amplifier 30, to the ground provided within the operational amplifier 30. Together therewith, the discharge current discharged from the pixel capacitance 18 of the liquid crystal cells flow through the data lines 20, the output pads 28, and the first protective resistors 32, to the inverting input terminal of the operational amplifier 30.

Accordingly, a portion of an image equivalent to one line that has been displayed on the liquid crystal panel 12 becomes undisplayed.

Thereafter, the gate driving circuit 14 switches from the current gate line 22 to a next gate line 22, and the above-described process is repeated. Accordingly, the entire image becomes undisplayed on the liquid crystal panel 12.

As described above, in the liquid crystal display device of the present exemplary embodiment, the inverting input terminal of the operational amplifier is connected the output terminal through the first protective resistor and second protective resistor. Together therewith, the inverting input terminal of the operational amplifier is connected to the output terminal through the capacitor. Due thereto, the potential of the DC component which is output from the output pads is lowered to the same potential as the potential of the input signal by the protective resistors. Together therewith, the AC component of the output signal output from the output terminal of the operational amplifier is feedbacked to the inverting input terminal, through the capacitor connected between the output terminal (OUT) and the inverting input terminal. Accordingly, the oscillation condition is not met, and therefore, the liquid crystal display device of the present exemplary embodiment can maintain the oscillation stability of the operational amplifier.

In the exemplary embodiment, a case where the present invention is applied to the liquid crystal panel 12, has been described. However, the present invention can be applied to other displays, such as a FED (Field Emission Display), plasma display, or an organic EL display.

Further, in the exemplary embodiment, a case where the operational amplifier capable of rail-to-rail operation is applied, has been described. However, instead of operational amplifier capable of rail-to-rail operation, a sink-and-source type operational amplifier may be applied.

Moreover, in the above-described exemplary embodiment, a case where operational amplifier is applied as the impedance conversion section, has been described. However, an attenuator may be applied as the impedance conversion section.

What is claimed is:

1. An output circuit comprising:
an impedance conversion section, that includes an output terminal and a feedback input terminal, and that converts impedance;
a first resistor that includes a first end connected to the output terminal of the impedance conversion section, and a second end connected to a load;
a second resistor that includes a first end connected to the second end of the first resistor, and a second end connected to the feedback input terminal of the impedance conversion section; and
a capacitor that includes a first end connected to the output terminal of the impedance conversion section, and a second end connected to the feedback input terminal of the impedance conversion section.

2. The output circuit according to claim 1, wherein the first resistor and the second resistor are protective resistors for an accumulated static charge.

3. The output circuit according to claim 1, wherein the impedance conversion section is an operational amplifier, and wherein the feedback input terminal is an inverting input terminal of the operational amplifier.

4. A display device driving circuit that drives a display device, comprising:
a plurality of output circuits according to claim 1,
wherein the impedance conversion section is a driver that drives the display device as the load, based on an output signal outputted from the output terminal.

5. The display device driving circuit according to claim 4, wherein the display device is driven by electric current that flows corresponding to the output signal output from the output terminal of the impedance conversion section.

6. The display device driving circuit according to claim 5, wherein the display device is a liquid crystal display device.
